(19) United States
(12) Patent Application Publication
(10) Pub. No.: US 2012/0315738 A1
(43) Pub. Date: Dec. 13, 2012

(54) METHOD OF MANUFACTURING SEMICONDUCTOR DEVICE

(75) Inventor: Hirotaka KOBAYASHI, Tokyo (JP)

(73) Assignee: ELPIDA MEMORY, INC., Tokyo (JP)

(21) Appl. No.: 13/493,443

(22) Filed: Jun. 11, 2012

(30) Foreign Application Priority Data
Jun. 10, 2011 (JP) 2011-129987

(51) Int. Cl. H01L 21/762

(52) U.S. Cl. 438/424; 257/E21.546

(57) ABSTRACT

The present invention provides a method of manufacturing a semiconductor device. An insulating-separating portion, which surrounds an electrode penetrating a substrate, is filled with a stacked structure of at least two stages, including a first stage of insulating film and a second stage of insulating film. When at least one of the first and second stages of insulating films has a seam, the seam is stopped by the region in the bottom of the second stage of insulating film that does not have a seam in at least the bottom thereof, thereby increasing mechanical strength. It is possible to prevent the inner region of the insulating-separating portion from being isolated.

### BACKGROUND OF THE INVENTION

1. Field of the Invention

The present invention relates to a method of manufacturing a semiconductor device, and more particularly, to a method of manufacturing a semiconductor device having an electrode that penetrates a semiconductor substrate.

2. Related Art

Recently, along with the high functionality and diversification of semiconductor devices, semiconductor devices that are integrated by stacking a plurality of semiconductor chips on each other in the lengthwise direction were proposed. Such a semiconductor device is configured such that electrical connection is established between the semiconductor chips using an electrode that penetrates a semiconductor substrate (so called a through silicon (or substrate) via: hereinafter abbreviated as “TSV”) of the semiconductor chips.

Since the TSV is formed so as to penetrate the semiconductor substrate, it is necessary to provide insulation between the semiconductor substrate and the TSV. Therefore, technologies of separating the TSV from a semiconductor layer in a device-forming region using a ring-shaped insulating-separating portion (also referred to as an insulating ring) were proposed (JP2009-111061A and JP2007-123857A).

There are a so-called ‘via first’ scheme, in which an insulating ring is formed by forming a ring-shaped trench from a main surface side of a semiconductor substrate and then filling the trench with an insulating film before semiconductor elements are formed on the main surface, and a so-called ‘via last’ scheme, in which the insulating ring is formed after the semiconductor elements are formed.

In the ‘via first’ scheme, it is necessary to form the ring-shaped trench, which is to be filled with the insulating film, from the main surface side of the semiconductor substrate in advance, for example, to a depth ranging from 40 μm to 50 μm and at a width from 2 μm to 3 μm (an aspect ratio from 13 to 25), and to fill the inside of the trench with the insulating film so as to have an excellent coverage.

The method of forming the insulating ring, disclosed in JP2007-123857A, is as follows. First, as shown in FIG. 1, a ring-shaped trench corresponding to the shape of an insulating ring 110 is formed by dry-etching a silicon substrate 101. In subsequence, a thin SiN film 111 is formed, and a SiO₂ film 112 is formed by chemical vapor deposition (CVD) such that the inside of the trench is filled. Afterwards, the portion of the SiO₂ film 112 and the portion of the SiN film 111 that are formed in the region other than the trench are removed, thereby producing the insulating ring 110. In the subsequent process, semiconductor devices and wiring layers are formed on the substrate outside the insulating ring 110 (FIG. 2), and the backside is mechanically polished in order to thin the substrate (FIG. 3). Here, the substrate is thinned until the bottom of the insulating ring is exposed. After that, an electrode (TSV) 120 is formed inside the insulating ring 110, such that the TSV extends from the backside to the surface of the silicon substrate 101 (FIG. 4).

When the inventor has studied the foregoing method of forming the insulating ring, it was found that the following problems may cause. A silicon oxide film deposited by CVD is formed so as to be conformal with respect to the shape of the trench. That is, the silicon oxide film inside the trench is formed such that it grows from both sidewalls of the trench so as to join in substantially the central portion of the width of the trench, thereby forming a seam 112S. Due to this, the filling of the trench is completed. As shown in FIG. 3, when the semiconductor substrate is thinned by polishing the backside thereof, the seam 112S is in the state of reaching the backside 101B of the substrate from the main surface 101A of the substrate. FIGS. 5A and 5B show conceptual views of the insulating ring after the filling. In a deposition method using CVD, the thickness of the film is not completely uniform, and thus voids 112V may remain in the seam 112S (see FIG. 5A). In addition, after the backside polishing, the seam 112S left in the insulating ring continuously extends from the main surface side to the backside of the substrate. Due to this structure, it is easy for the inner portion 110 in and the outer portion 110 out of the insulating ring to separate from each other. When the inner and outer insulating ring portions are separated from each other, the substrate inside the insulating ring is isolated (see FIG. 5B). In the easily separable state, when stress is applied to the TSV, for example, in the process of stacking a chip, the substrate inside the insulating ring moves so as to apply stress to an interlayer insulating film 131 having electrical lines, the interlayer insulating film 131 covering the surface of the substrate, and to an insulating film 132 that covers the backside of the substrate. This may cause damage to the chip, for example, by forming cracks 200. When cracks reach a device region, there is a danger that the semiconductor elements may be destroyed (FIG. 4).

The method of forming the insulating ring, disclosed in JP2009-111061 A, is substantially the same, and may lead to problems that are substantially the same above.

In the meantime, as a void-free method of filling a trench with an insulating film without forming such a seam, there is a method of depositing a flowable material, such as a spin-on dielectric (SOD) film. However, the insulating film, which is formed in this method, has poor resistance to chemicals, and is greatly recessed due to being exposed to etching when a semiconductor element or the like is formed on the main surface of the substrate. Thus, the flatness of the surface of the substrate may be damaged. In addition, when the film is subjected to densification (thermal densification) in order to increase the resistance to etching, the volume of the SOD film or the like is greatly shrunk due to thermal densification, and in that case, the flatness is damaged. Furthermore, the substrate may be deformed by tensile stress that is applied in the depth direction.

### SUMMARY

The present invention has been devised in order to solve the foregoing problem by forming at least two stages of insulating films that are filled in an insulating ring.

According to an embodiment of the invention, provided is a method of manufacturing a semiconductor device. The method includes:

forming a trench in a first surface of a substrate such that a depth of the trench is formed in a direction toward a second surface of the substrate, the second surface being disposed in opposite side of the first surface in the substrate;

forming a first insulating film on the first surface of the substrate to fill the trench with the first insulating film;

removing a portion of the first insulating film extending from an intermediate position of the depth of the trench onto the first surface of the substrate with leaving a remaining portion of the first insulating film at a bottom of the trench; and

forming, after removing the portion of the first insulating film, a second insulating film on the first surface of the substrate to fill a remaining portion of the trench with the second insulating film, the remaining portion of the trench being not filled the first insulating film.

According to another embodiment of the invention, provided is a method of manufacturing a semiconductor device. The method includes:

selectively removing a main surface of a substrate to form a trench having a first sidewall and a second sidewall, the first and second sidewalls being opposed to each other;

forming a first sidewall insulation film and a second sidewall insulation film in the trench to fill the trench, the first sidewall insulation film being grown from the first sidewall, the second sidewall insulation film being grown from the second sidewall;

removing portions of the first and the second sidewall insulation films extending from an intermediate position of a depth of the trench to an opening of the trench; and

filling the trench, after the removing the portions of the first and the second sidewall insulation films, with a third insulation film.

According to embodiments of the invention, an insulating film, which is first formed inside the trench, is etched, and the trench is filled again with another insulating film, so that the insulating films inside the insulating ring form a two-stage structure including upper and lower stages. When one of the two stages of the insulating films has a seam due to deposition in the central portion of the trench in the width direction, the seam is capped by the stacked portion. This, consequently, prevents the substrate and the portion of inside the insulating ring from being separated in the shape of a column. That is, it is possible to prevent the portion of the substrate that is inside the insulating ring from being isolated. Therefore, since the portion (the TSV-forming portion) of the substrate inside the insulating ring does not move even if stress is applied to the TSV, for example, when stacking a chip, there is no danger that the interlayer insulating film is subjected to stress or the like. Consequently, mechanical strength is increased. As a result, according to the semiconductor device that has the insulating ring, which is manufactured by the method of the invention, it is possible to increase the yield of production.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 3 and 4A are vertical cross-sectional views depicting process of manufacturing the semiconductor device that has a TSV using an insulating ring in one example of the related art and FIG. 4B is a horizontal cross-sectional view of the FIG. 4A;

FIG. 5A and FIG. 5B are conceptual views depicting a problem of the insulating ring in one example of the related art;

FIGS. 6, 7, 8A, 9-11 and 12A are vertical cross-sectional views depicting processes of manufacturing a semiconductor device according to one embodiment of the invention, FIG. 8B is a partial enlargement of FIG. 8A and FIG. 12B is a horizontal cross-sectional view of FIG. 12A;

FIGS. 13A and 13B are schematic cross-sectional view depicting a modified example of the insulating ring according to one embodiment of the invention;

FIG. 14A is a schematic cross-sectional views depicting the effect of the modified embodiment of the insulating ring according to one embodiment of the invention in comparison with the insulating ring according to the related art (FIG. 14B);

FIG. 15A and FIG. 15B are schematic cross-sectional views depicting another modified example of the insulating ring according to one embodiment of the invention;

FIGS. 16A to 16C are schematic cross-sectional views depicting a further modified example of the insulating ring according to one embodiment of the invention;

FIG. 17A to FIG. 17D are process cross-sectional views depicting processes of manufacturing a semiconductor device according to still another embodiment of the invention;

FIG. 18A is a schematic vertical cross-sectional view of the semiconductor device according to the still another embodiment of the invention; and

FIG. 18B is a horizontal cross-sectional view of FIG. 18A.

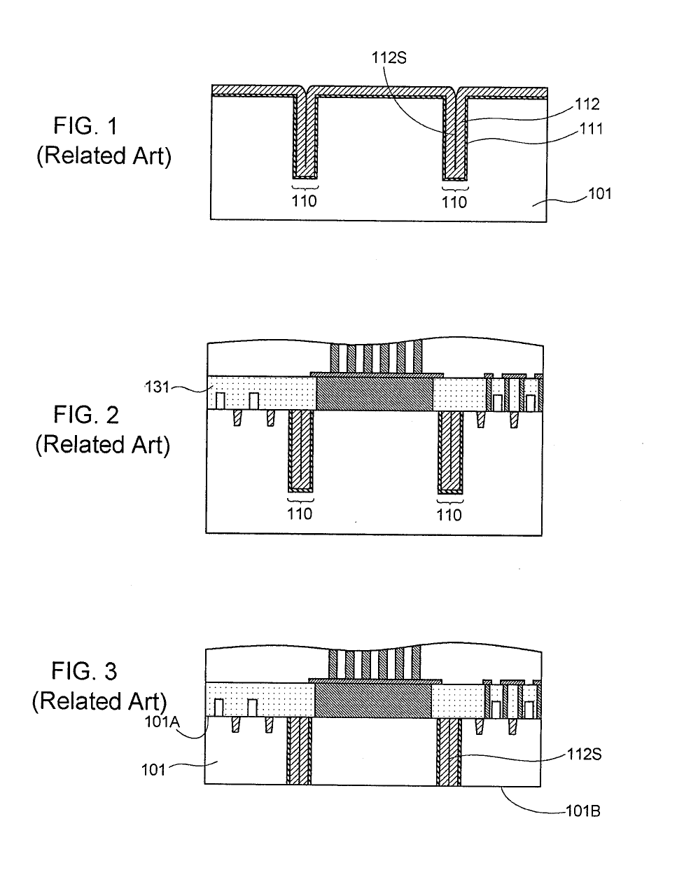

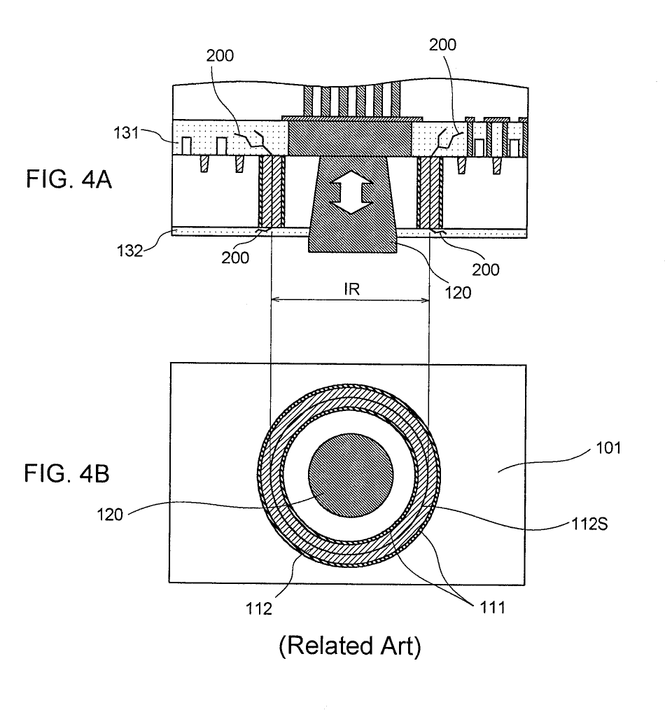

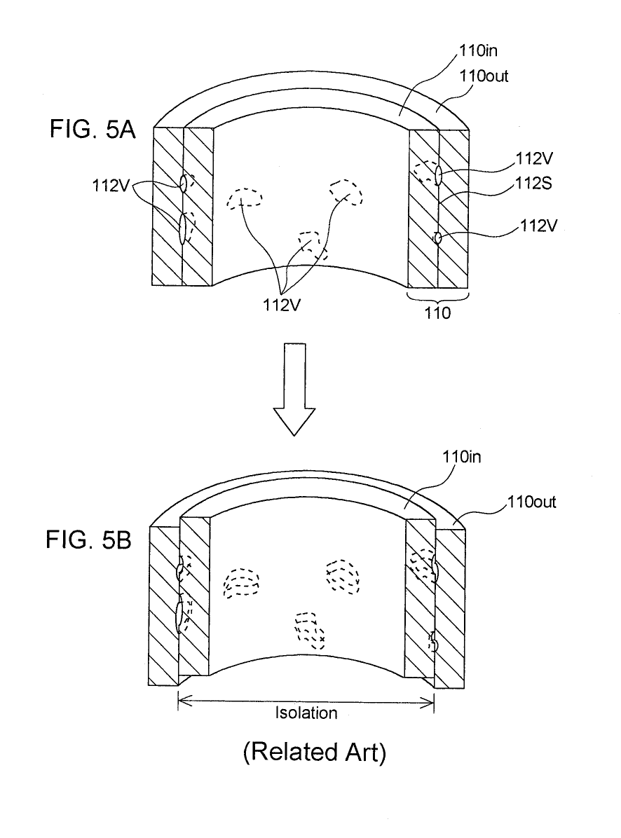

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### First Exemplary Embodiment

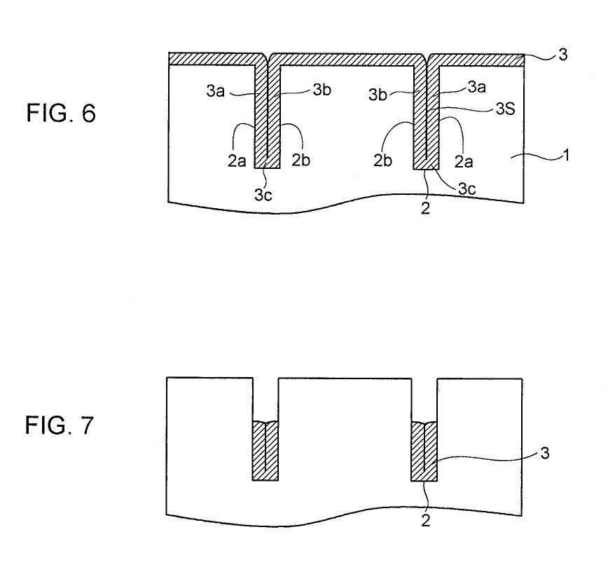

First, as shown in FIG. 6, a ring-shaped trench (a circular ring-shaped trench) 2 having a depth 50 μm and a width 2 μm is formed in a main surface side (first surface side) of a semiconductor substrate (silicon substrate) 1 by dry etching. The processing of the trench 2 includes forming a silicon nitride film (not shown) as a mask on the silicon substrate 1, and then the ring-shaped opening is formed using photolithography technology. In subsequence, the main surface of the silicon substrate 1 is selectively removed by etching using the shaped silicon nitride film as the mask. After the silicon substrate 1 is etched, the shaped silicon nitride film is removed. Alternatively, a next first insulating film may be formed without removing the shaped silicon nitride film.

In subsequence, a first insulating film 3 is deposited on the main surface of the silicon substrate 1, including the inside of the trench. Here, as the first insulating film 3, a non-doped silicate glass (NSG) film is deposited by low pressure chemical vapor deposition (LPCVD) using ozone and TEOS (Tetraethyl orthosilicate) as raw materials. In the first insulating film 3, which is formed by this deposition method, a first sidewall insulation film 3a, which grows from one sidewall (a first sidewall 2a: herein an outside wall of a ring-shaped trench) except for the bottom (a bottom insulation film 3c) at the startup of the deposition, and a second sidewall insulation film 3b, which grows from the other sidewall (a second sidewall 2b: herein an inside wall of the ring-shaped trench), are joined to form a seam 3S in substantially the central portion of the width of the trench.

The first insulating film 3 is not limited to the silicon oxide film, such as the TEOS-NSG film, but can be implemented with any insulating films, such as a silicon nitride film, as long as they are electrically insulating. The TEOS-NSG film produced by LPCVD is advantageous in that the costs of raw materials and a manufacturing apparatus are inexpensive.

In subsequence, as shown in FIG. 7, the excess portion of the first insulating film 3 on the silicon substrate 1 is removed by etching (dry etching or wet etching), chemical mechanical polishing (CMP), or the like. Particularly, the first insulating film is removed to substantially the half of the depth of the ring-shaped trench 2 by the etching. This exemplary embodiment shows the state of being etched back by anisotropic dry etching. The amount of the first insulating film 3 that is etched back is not limited to substantially the half of the depth of the trench, but may be deeper than substantially the half of the depth of the trench or in contrast, be shallower than substantially the half of the depth of the trench so that the first insulating film remains even after at least the backside (second surface side) of the semiconductor substrate 1 is polished.

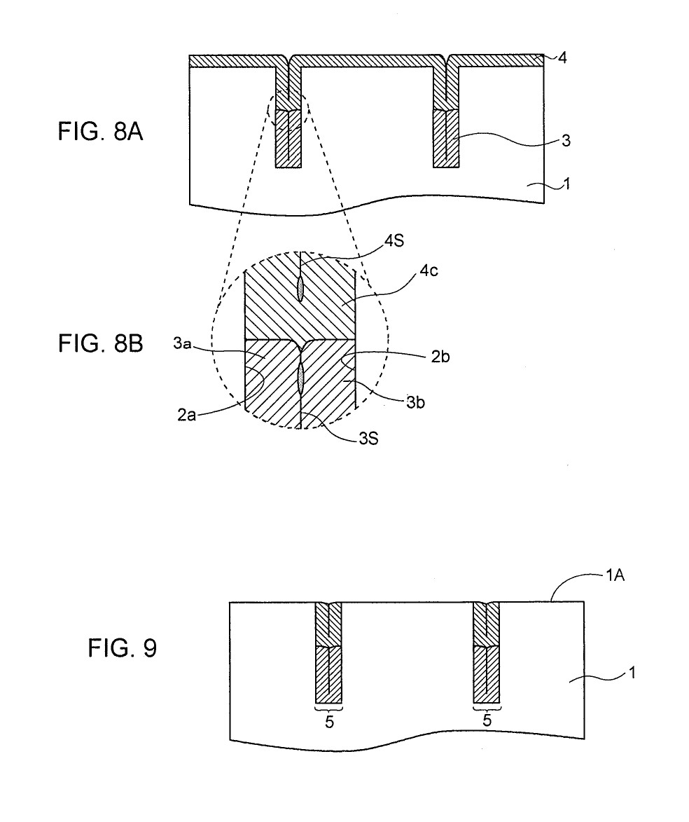

Afterwards, as shown in FIG. 8A, a second insulating film 4 is deposited by CVD, in substantially the same way as in the first insulating film 3. Although the second insulating film 4 forms a seam 4S in substantially the central portion of the width of the trench except for the bottom at the startup of the deposition, the seam 3S of the first insulating film 3 and the seam 4S of the second insulating film 4 are not continuous but are divided by the second insulating film 4c on the bottom at the startup of the deposition (see a partial enlargement of FIG. 8B). Since the seams 3S and 4S are discontinued, mechanical strength is increased. The thickness of the bottom at the startup of the deposition of the second insulating film 4 is substantially the half of the width of the trench of the ring-shaped trench. In this exemplary embodiment, a region without the seam 4S is formed at a thickness of about 1 μm. The second insulating film 4 may be called as a “third insulation film” related to the first and second sidewall insulation films 3a and 3b.

In subsequence, the main surface 1A of the silicon substrate is exposed by removing the excess portion of the second insulating film 4 on the silicon substrate 1 by etching (dry etching or wet etching) or CMP, and the inside of the insulating ring is filled by stacking the first insulating film 3 and the second insulating film 4 thereon (FIG. 9).

Afterwards, in order to perform thermal densification of the first and second insulating films, with which the inside of the ring-shaped trench is filled. The thermal densification was performed by heat treatment at 1000° C. in a non-oxidizing atmosphere (an inert gas atmosphere, such as nitrogen) for 60 minutes. After completion of the heat treatment, an insulating ring 5 was formed. The thermal densification can be performed at a temperature ranging from 900° C. to 1000° C. Although the processing time may vary depending on the processing temperature, the depth of the ring-shaped trench, the width or the like, sufficient thermal densification may be performed when performed for about 30 minutes or longer. The upper limit of the processing time is not specifically limited, and there is no problem in insulation performance even if the thermal densification is performed longer than necessary. However, since energy cost increases, it is preferable that the thermal densification is performed typically for 90 minutes or shorter. In addition, the thermal densification may be performed respectively for the first insulating film 3 and the second insulating film 4.

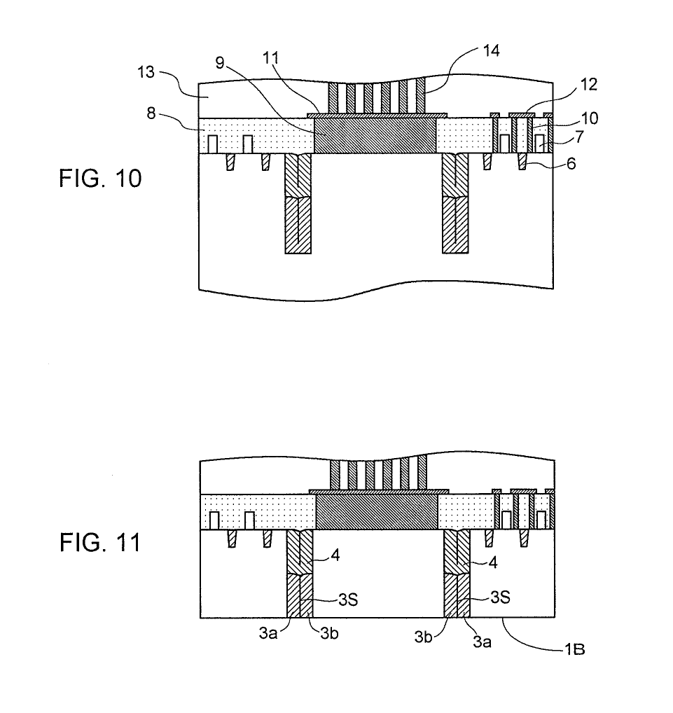

After the process up to FIG. 9 is completed in this way, a typical process of forming a semiconductor device is performed. That is, as shown in FIG. 10, the process of forming a shallow trench isolation (STI), which will form a device separation region, the process of forming a gate electrode 7, the process of forming a diffusion layer (not shown), and the like are performed.

In addition, a first interlayer insulating film 8 is formed, and a contact electrode 9, which will be connected to a TSV that is to be formed later, and a contact plug 10, which will be connected to a respective diffusion layer of transistors, are formed in the first interlayer insulating film 8. Afterwards, a wiring layer, which includes a line 11 that is connected to the contact electrode 9 and a line 12 that is connected to the contact plug 10, is formed.

In subsequence, due to the formation of a second interlayer insulating film 13 and a contact 14 for external connection, the manufacturing process on the main surface side of the silicon substrate is completed.

Afterwards, as will be described later, processing on the backside of the silicon substrate is performed.

First, the silicon substrate 1 is thinned by backside polishing. This backside polishing is continued until the insulating ring is exposed. Due to this polishing, as shown in FIG. 11, the insulating ring, which penetrates to the backside 1B of the silicon substrate 1, is completed. In this way, a TSV-forming region, which is surrounded by the insulating ring, is formed.

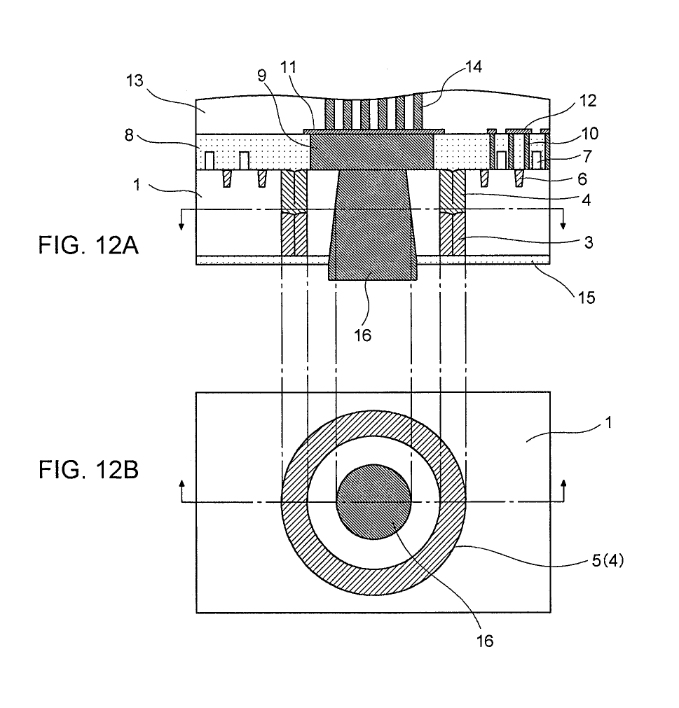

In subsequence, as shown in FIG. 12, a backside insulating film 15, which covers the backside 1B of the silicon substrate (including the TSV-forming region), is formed. Subsequently, an opening, which penetrates the backside insulating film 15 and the silicon substrate 1 from the backside of the silicon substrate and exposes the lower surface of the contact electrode 9, is formed in the TSV-forming region. In subsequence, an electrode 16 for TSV is formed so as to fill the opening.

The electrode 16 is formed by depositing a copper-containing film as a seed by sputtering or the like, and filling a copper film by plating.

For example, first, titanium and copper are sequentially formed as a plating seed layer in the opening and on the surface of the initial backside insulating layer, i.e. on the whole of the backside 1B of the silicon substrate, by sputtering or metal organic chemical vapor deposition (MOCVD). In subsequence, a photoresist layer (not shown) is formed. An opening pattern is formed by performing known lithography on the photoresist layer, and the inside of the opening is filled with copper by plating using the opening pattern as a mask.

Afterwards, for example, the photoresist layer is removed using an organic solvent such as acetone, and then the excess amount of copper and titanium of the plating seed layer is removed by wet etching using sulphuric acid or hydrofluoric acid. Through the foregoing process, as shown in FIG. 12, the electrode 16 that includes an internal through electrode portion and an electrode pad portion can be formed.

The electrode 16 can be formed from one or two or more kinds of conductive materials including a metal such as copper, aluminum, titanium, tungsten, or alloys thereof; a metal silicide such as titanium silicide or tungsten silicide; an electrically conductive inorganic material such as titanium nitride; and polysilicon doped with an n-type impurity such as phosphorus or a p-type impurity such as boron. It is preferred that the electrode be made of a metal such as titanium or copper.

### Modified Examples

In subsequence, modified examples of the first exemplary embodiment will be described.

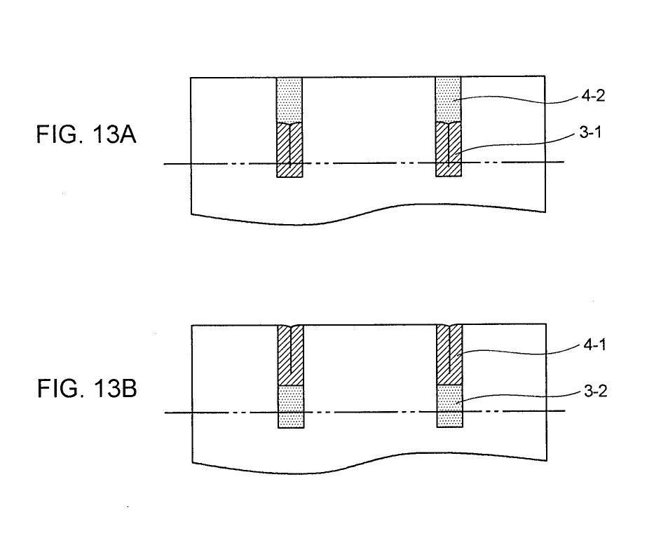

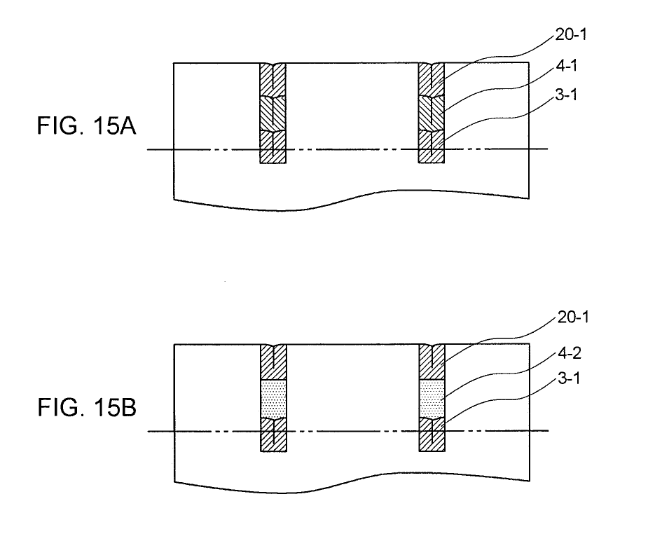

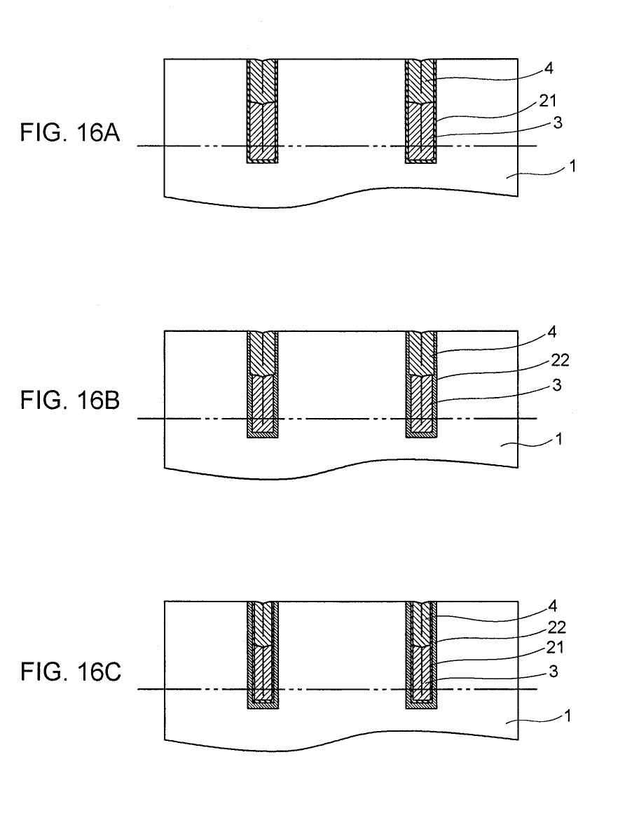

In the foregoing explanation, both the first insulating film 3 and the second insulating film 4 are formed by CVD, as the films that have the seam 3S and the seam 4S, respectively. However, the invention is not limited to this construction, but one of the first and second insulating films can be formed by first deposition method, in which a seam is formed in the central portion of the width of the trench except for the bottom at the startup of the CVD, and the other insulating layer can be formed by second deposition method, in which no seam is formed. FIG. 13A shows the multi-stage structure including a first insulating film 3-1, which is formed by the first deposition method, and a second insulating film 4-2, which is formed by the second deposition method. In contrast, FIG. 13B shows the multi-stage structure including a first insulating film 3-2, which is formed by the second deposition method, and a second insulating film 4-1, which is formed by the first deposition method. In FIG. 13A and FIG. 13B, a two-dot chain line indicates the backside position after being polished, which is the same as in FIG. 15A, FIG. 15B, FIG. 16A to FIG. 16C. The second deposition method can form a film without a seam by filling a flowable insulating material inside the trench. The second deposition method may be implemented as a method of forming an insulating coating film such as a spin-on dielectric (SOD) film, a flowable CVD method, or the like. The formation of the insulating film without a seam further increases mechanical strength.

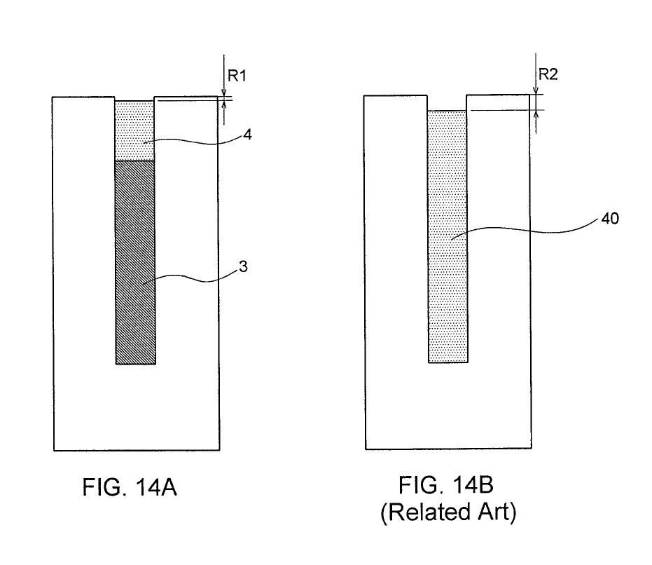

In addition, the insulating film formed by the second deposition method can be stacked into the two stages. The insulating film formed by the second deposition method is usually subjected to thermal densification. In the invention, since at least two stages of insulating films are stacked, thermal densification can be performed for each stage of the insulating film, and thus the amount of shrinkage (the amount of recession) in the depth direction becomes less than that of one stage of the insulating film. For example, FIG. 14A shows the state in which a first insulating film 3 is formed of a flowable insulating material, followed by etching back and thermal densification, and then a second insulating film 4 is formed of a flowable insulating material, followed by planarization and thermal densification. FIG. 14B shows the state obtained by a method in an example of the related art, in which the inside of a ring-shaped trench is filled with an insulation material 40, followed by planarization and thermal densification. As shown in FIG. 14A, forming two stages of a flowable insulating material increases mechanical strength and improves the flatness of the surface of the substrate compared to the case in which one stage is formed (FIG. 14B). In FIG. 14A and FIG. 14B, R1 and R2 indicate the amount of recession after the thermal densification. As for an insulating film, which is formed by the first deposition method, the same effects can be obtained by performing thermal densification in respective stages.

In the present invention, in addition to the two-stage structure including the first insulating film and the second insulating film, the insulating ring having more stages can be stacked. For example, FIG. 15A shows the structure in which three stages of insulating films (a first insulating film 3-1, a second insulating film 4-1, and a third insulating film 20-1), which are formed by the first deposition method, are stacked in this order. In this case, mechanical strength is further increased due to the region of the discontinuous seam being increased to two portions. In addition, FIG. 15B shows a case in which an insulating film, such as an SOD film, formed by the second deposition method is used for an intermediate portion (a second insulating film 4-2), and upper and lower insulating films, such as TEOS-NSG films, are used for the first insulating film 3-1 and the third insulating film 20-1. As described above, since an insulating film made of a flowable material, such as an SOD film, has poor resistance to chemicals, insulating films that have excellent resistance to chemicals are formed over and under the insulating film made of a flowable material. The insulating films having excellent resistance to chemicals are preferably exposed from both the main surface side and the polished backside of the substrate. In addition, since the insulating film made of a flowable material does not form a seam, mechanical strength is increased. The process of making the insulating films, which are stacked in the multiple stages, becomes more complicated with the increasing number of the insulating films. Therefore, the number of the stages is preferably 5 or less, and sufficient effects can be obtained using the shown structure in which three stages of insulating films are provided.

In addition to the insulating films, which are stacked in this way, a sidewall-insulating film can be formed on the sidewalls of the ring-shaped trench, and inside the ring-shaped trench that has the sidewall-insulating film, an insulating film having the stacked structure of the invention can be formed. For example, when the conductive film that has a metal material, such as copper, as the main component is used for the electrode for TSV, a barrier layer is preferably formed in order to prevent the metal, such as copper, from diffusing into the device-forming region. Such a barrier film can be formed on the sidewalls of the ring-shaped trench. Such a barrier film can be implemented as a silicon nitride film. In some cases, as for the SOD film, when a film is not a perfect silicon oxide film right after being formed, it may be required to perform oxidizing heat treatment in order to convert this film into the silicon oxide film. In that case, an anti-oxidation film, which prevents the silicon substrate constituting the sidewalls of the ring-shaped trench from being unnecessarily oxidized, can be formed. The anti-oxidation film can be implemented as a silicon nitride film.

Alternatively, a thermal oxidation film can be formed on the inside wall of the ring-shaped trench by actively performing thermal oxidation inside the ring-shaped trench. In the case of a silicon substrate, a thermal silicon oxide film is formed, but about half of the film thickness is formed on the original silicon substrate side. When the silicon oxide film is used as the first insulating film, the thermal silicon oxide film is removed likewise when the first insulating film is etched back. Thus, no thermal silicon oxide film sometimes remains on the side of the second insulating film. In addition, when the inside of the ring-shaped trench is thermally oxidized in the state in which a mask silicon nitride film, which was used as a mask when forming the ring-shaped trench, is left, the mask silicon nitride film acts as an anti-oxidation film, thereby preventing the surface of the substrate from being oxidized. In addition, when etching back the first insulating film, the residual mask silicon nitride film may act as an etching mask, so that about half of the thermal silicon oxide film (the portion that is formed on the original silicon substrate) may reside without being etched. Furthermore, since the thermal silicon oxide film grows from the original silicon substrate due to deposition and expansion, it becomes a film that applies compressive stress in the depth direction of the ring-shaped trench. When thermal densification is performed on the first and second insulating films, the volume typically shrinks, thereby forming a film that applies tensile stress in the direction of the depth of the trench. If most of the inside of the ring-shaped trench is the film that applies tensile strength, in some cases, the main surface of the semiconductor substrate around the insulating ring may be caused to deform. However, when a thermal oxidation film that applies compressive stress is formed inside the trench, part or all of the tensile stress can be canceled by the compressive stress, thereby preventing the substrate main surface side from being deformed. In addition, when the barrier film is formed using the silicon nitride film after the thermal oxidation film is formed; the thermal oxidation film is not etched when the first insulating film is etched back.

FIG. 16A shows an example in which a silicon nitride film 21 is formed as a barrier film or an anti-oxidation film on the inside wall of the ring-shaped trench. FIG. 16B shows a case in which a thermal silicon oxide film 22 is formed on the inside wall of the ring-shaped trench. FIG. 16C shows a case in which a thermal silicon oxide film 22 is formed on the inside wall of the ring-shaped trench and then a silicon nitride film 21, which will form a barrier film, is formed thereon.

In this exemplary embodiment, as in FIG. 12B, the insulating ring 5 and the electrode 16 are formed circular (cylindrical and columnar, respectively). However, these are not intended to be limiting, other shapes such as a rectangle may be employed.

In addition, although single insulating ring is formed, a multiple rings of double or more can be provided. For example, a construction that can be provided includes a first insulating ring (an insulating-separating portion), which is formed in the TSV side, and a second insulating ring (an insulating-separating portion), which is spaced apart from the first insulating ring, with a silicon region of a semiconductor substrate being interposed therebetween on the outer circumference of the first insulating ring. Due to the multiple-ring structure, it is possible to ensure insulation even if the width of the respective insulating rings is decreased. In addition, due to the width of the insulating rings being decreased, each thickness of the first insulating film and the second insulating film is decreased, thereby achieving the effect of increased yield.

### Second Exemplary Embodiment

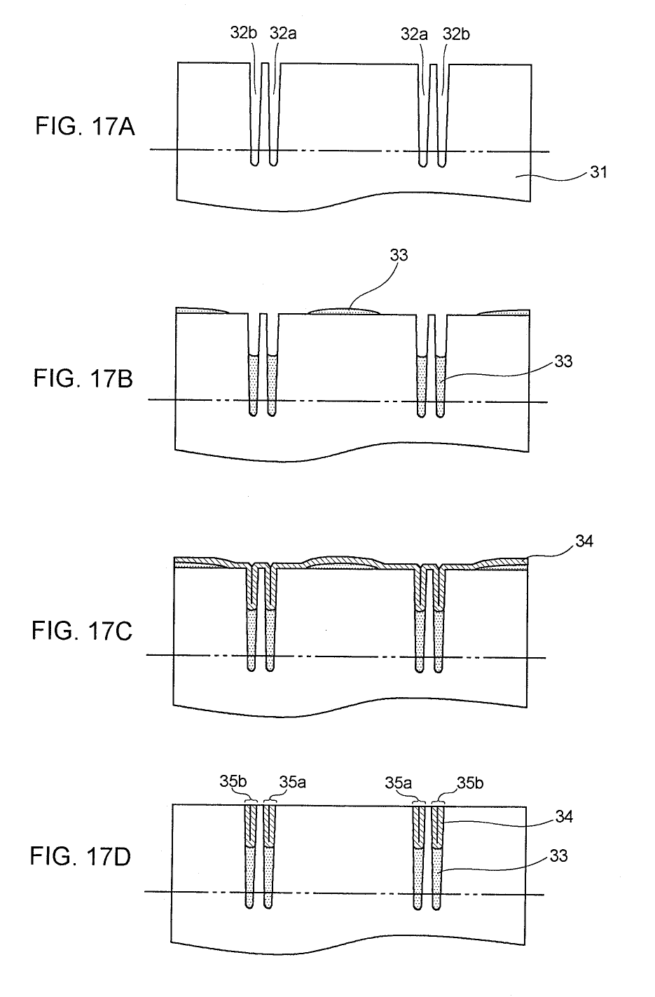

In the first exemplary embodiment, etching back is performed after the first insulating film is formed. However, in some cases, the etching back is not necessary when the first insulating film is made of a flowable insulating material. FIG. 17A to FIG. 17D are process cross-sectional views depicting a method of manufacturing a semiconductor device, which includes a deposition process using a flowable insulating material by flowable CVD.

First, as shown in FIG. 17A, ring-shaped trenches 32a and 32b are formed in a silicon substrate 31 in order to form insulating rings. In this exemplary embodiment, a case, in which double insulating rings, including a first insulating ring and a second insulating ring, are formed, is presented. When the double insulating rings are formed, each width of the trenches is smaller than that of the trench of a single insulating ring, but the aspect ratio is increased due to the decreased trench width. A trench having a large aspect ratio tends to make it difficult to etch, and as shown in the figure, the trenches are tapered with the width of the bottom thereof being narrow. When the width of the bottom of the trench is narrow due to the tapered shape, the mechanical strength of a film such as a TEOS-NSG film, which is formed by CVD, tends to decrease since it becomes easier for voids to be in the seam.

The flowable insulating material can fill the bottom portion of the trench, which is narrowed, without leaving voids. Here, a method, such as spin coating, is a method of forming a thin film in the direction from a dropping position to the outer circumference by centrifugal force. The material is introduced into the ring-shaped trench, sequentially from the position adjacent to the dropping position. Here, when the insulating material is applied to an amount with which the trench is filled up to the intermediate portion thereof, it is impossible to maintain uniformity in the wafer surface. Therefore, typically, the trench is completely filled and a predetermined film thickness is formed on the substrate (wafer). In contrast, according to the deposition using flowable CVD, deposition is substantially uniform over the substrate. In addition, the material is flowable, and drops and flows into the trench due to gravity. At this time, the flowing material drops and flows into the trench by dragging the deposit around the trench due to the surface tension thereof. Due to the control over the amount of deposition, it is possible fill the trench to a predetermined depth with the deposit (first insulating film 33) in the state of being recessed from the opening of the trench (FIG. 17B). Due the use of this deposition method, the etching back of the first insulating film, which is described in the first exemplary embodiment, becomes unnecessary.

After the first insulating film 33 is thus formed, the second insulating film 34 is similarly formed by the first deposition method, which is presented in the first exemplary embodiment (FIG. 17C). Even though the bottom of the trench is filled with the first insulating film 33 without a seam and the second insulating film 34 having a seam is filled thereon, after the backside polishing, it is possible to provide the structure in which the seam of the insulating film is not continuous from the surface to the backside of the substrate, thereby increasing mechanical strength.

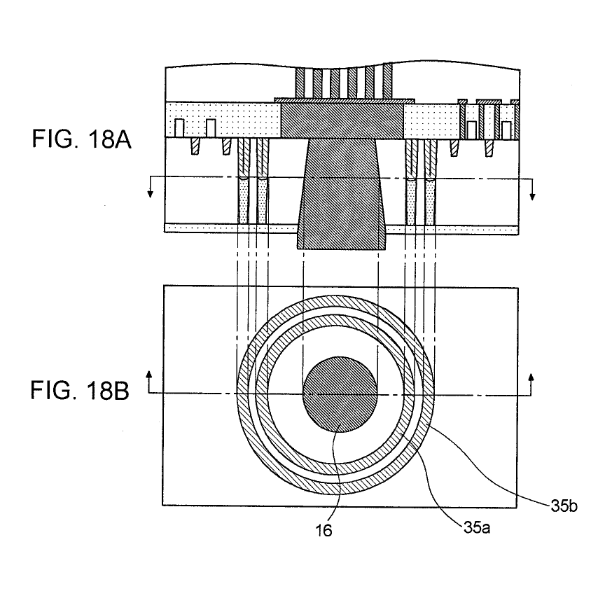

In subsequence, as shown in FIG. 17D, the main surface side of the silicon substrate is planarized, thereby completely producing double insulating rings, including a first insulating ring 35a and a second insulating ring 35b around the first insulating ring 35a. After that, it is possible to produce a semiconductor device, as shown in FIG. 18, by forming a transistor or the like on the main surface side, polishing the backside of the substrate, and forming an electrode 16 for TSV in the same fashion as in the first exemplary embodiment.

In the meantime, the deposition of the first insulating film in the second exemplary embodiment is not limited to the flowable CVD, but can be executed by any methods that can ensure the same effects. For example, a method for uniformly applying a substrate surface with an insulating film by, for example, spraying is possible.

What is claimed is:

1. A method of manufacturing a semiconductor device, comprising:
forming a trench in a first surface of a substrate such that a depth of the trench is formed in a direction toward a second surface of the substrate, the second surface being disposed in opposite side of the first surface in the substrate;
forming a first insulating film on the first surface of the substrate to fill the trench with the first insulating film;
removing a portion of the first insulating film extending from an intermediate position of the depth of the trench onto the first surface of the substrate with leaving a remaining portion of the first insulating film at a bottom of the trench; and
forming, after removing the portion of the first insulating film, a second insulating film on the first surface of the substrate to fill a remaining portion of the trench with the second insulating film, the remaining portion of the trench being not filled the first insulating film.

2. The method as claimed in claim 1, further comprising thinning the substrate by polishing the second surface to expose the first insulating film formed in the bottom of the trench.

3. The method as claimed in claim 1, wherein the trench is formed such that a shape of the trench appearing in the first surface is ring-shaped; and
the method further comprises forming, after forming the second insulating film, an electrode penetrating a region of the substrate surrounded by the ring-shaped trench.

4. The method as claimed in claim 1, wherein the first insulating film is formed so as to comprise a seam arranged along both sidewalls of the trench.

5. The method as claimed in claim 4, wherein the second insulating film is formed to cap the seam of the first insulating film from above.

6. The method as claimed in claim 1, wherein the second insulating film is formed such that a deposition rate on a bottom of the trench is faster than that on a sidewall of the trench.

7. The method as claimed in claim 1, further comprising:
removing a portion of the second insulating extending from another intermediate position of the depth of the trench onto the first surface of the substrate with leaving a remaining portion of the second insulating film in the trench;
forming, after removing the portion of the second insulating film, a third insulating film on the first surface of the substrate to fill a remaining portion of the trench with the third insulating film, the remaining portion of the trench being not filled the first and second insulating films.

8. The method as claimed in claim 1, wherein the first insulating film is formed by chemical vapor deposition.

9. The method as claimed in claim 1, wherein the first insulating film is formed by chemical vapor deposition using ozone and TEOS as raw materials.

10. The method as claimed in claim 1, wherein the second insulating film is formed by an SOD method.

11. The method as claimed in claim 1, wherein the second insulating film is formed by a flowable chemical vapor deposition method.

12. The method as claimed in claim 1, further comprising forming, after forming the second insulating film, a shallow trench isolation region in the first surface of the substrate.

13. The method as claimed in claim 1, further comprising forming, after forming the trench and before forming the first insulating film, a sidewall insulating film to cover a sidewall of the trench, the sidewall insulating film having a thickness such that the trench is not filled.

14. The method as claimed in claim 13, wherein the sidewall insulating film comprises a silicon nitride film.

15. The method as claimed in claim 13, wherein the sidewall insulating film is formed by oxidizing the substrate exposed in the trench.

16. A method of manufacturing a semiconductor device, comprising:
selectively removing a main surface of a substrate to form a trench having a first sidewall and a second sidewall, the first and second sidewalls being opposed to each other;
forming a first sidewall insulation film and a second sidewall insulation film in the trench to fill the trench, the first sidewall insulation film being grown from the first sidewall, the second sidewall insulation film being grown from the second sidewall;
removing portions of the first and the second sidewall insulation films extending from an intermediate position of a depth of the trench to an opening of the trench; and
filling the trench, after the removing the portions of the first and the second sidewall insulation films, with a third insulation film.

17. The method as claimed in claim 16, further comprising thinning the substrate by polishing a backside surface of the substrate to expose the first and second sidewall insulation films formed in the trench, the backside surface of the substrate being opposite the main surface.

18. The method as claimed in claim 16, wherein the selectively removing is performed such that a shape of the trench appearing in the main surface is ring-shaped; and
the method further comprises forming, after forming the third insulation film, an electrode penetrating a region of the substrate surrounded by the ring-shaped trench.

19. The method as claimed in claim 16, wherein the first sidewall insulation film and the second sidewall insulation film are joined to form a seam when the first and the second sidewall insulation films are formed in the trench, the seam being arranged along the first and the second sidewalls of the trench.

20. The method as claimed in claim 19, wherein the third insulation film is formed to cap the seam from above.
